(19) United States
(12) Patent Application Publication
(10) Pub. No.: US 2009/0152982 A1
(43) Pub. Date: Jun. 18, 2009

(54) ELASTIC WAVE DEVICE, FILTER DEVICE, COMMUNICATION MODULE AND COMMUNICATION APPARATUS

(75) Inventors: Michio MIURA, Kawasaki (JP); Suguru Warashina, Kawasaki (JP); Takashi Matsuda, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/336,139

(22) Filed: Dec. 16, 2008

(30) Foreign Application Priority Data
Dec. 17, 2007 (JP) 2007-325099

(51) Int. Cl. H01L 41/053

(52) U.S. Cl. 310/313 B

(57) ABSTRACT

An elastic wave device including a piezoelectric substrate, comb-like electrodes formed on the piezoelectric substrate, and a dielectric layer formed on the piezoelectric substrate. The dielectric layer formed on the piezoelectric substrate covers the comb-like electrodes and the thickness of the dielectric layer formed on the piezoelectric substrate is larger than the sum of the thickness of the comb-like electrodes and the thickness of the dielectric layer formed on the comb-like electrodes.

### CROSS-REFERENCE TO RELATED APPLICATIONS

This application is based upon and claims the benefit of priority of the prior Japanese Patent Application No. 2007-325099, filed on Dec. 17, 2007, the entire contents of which are incorporated herein by reference.

### FIELD

The present invention relates to an elastic wave device mounted in a communication apparatus.

### BACKGROUND

Surface Acoustic Wave (SAW) devices have been heretofore well-known as one kind of elastic wave-applied device. The SAW device is used in various circuits, such as a transmission band-pass filter, a reception band-pass filter, a local oscillation filter, an antenna duplexer, an IF filter, an FM modulator, etc., for example, in an apparatus which processes a radio signal with a frequency band of 45 MHz to 2 GHz.

The SAW device, for example, used in a band-pass filter has required improvements in various characteristics such as reduction of in-band loss, increase of out-of-band suppression, enhancement of temperature stability, etc. and has required reduction in device size with the advance of performance of cellular phone terminals or the like in recent years. Among those improvements, various methods have been proposed, such as a method of forming a silicon oxide film with different temperature characteristic signs on a piezoelectric substrate, to improve temperature characteristics.

For example, in JP-A-2003-209458, there has been disclosed a configuration in which an SiO₂ thin film is formed on a highly piezoelectric LiNbO₃ substrate to thereby improve temperature characteristics. In Japanese Patent No. 3841053, there has been disclosed a configuration in which surface roughness of an SiO₂ thin film is reduced by a lift-off method to thereby reduce device loss. According to the configuration disclosed in JP-A-2003-209458 or Japanese Patent No. 3841053, the temperature characteristic of an elastic wave device can be improved, for example, to ±20 ppm/° C. by adjustment of the thickness of the SiO₂ film.

### SUMMARY

According to an aspect of the invention, an apparatus includes an elastic wave device which has a piezoelectric substrate, comb-like electrodes formed on the piezoelectric substrate, and a dielectric layer formed on the piezoelectric substrate so that the comb-like electrodes are covered with the dielectric layer. The thickness of the dielectric layer formed on the piezoelectric substrate is larger than the sum of the thickness of the comb-like electrodes and the thickness of the dielectric layer formed on the comb-like electrodes.

Additional objects and advantages of the embodiment will be set forth in part in the description which follows, and in part will be obvious from the description, or may be learned by practice of the invention. The object and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

FIG. 1 is a plan view illustrating an elastic wave device according to an embodiment;

FIG. 2 is a sectional view along the line Z-Z in FIG. 1;

FIG. 3 is a model view where a simulation based on a finite element method is performed on the elastic wave device according to the embodiment;

FIG. 4 is a characteristic graph illustrating the relationship between the height of convex parts of a dielectric layer and the frequency temperature characteristic difference;

FIG. 5 is a characteristic graph illustrating the relationship between the height of convex parts of a dielectric layer and the frequency temperature characteristic difference;

FIG. 6 is a characteristic graph illustrating the relationship between the height of convex parts of a dielectric layer and the frequency temperature characteristic difference;

FIG. 7 is a characteristic graph illustrating the relationship between the height of convex parts of a dielectric layer and the frequency temperature characteristic difference;

FIG. 8 is a characteristic graph illustrating the relationship between the height of convex parts of a dielectric layer and the frequency temperature characteristic difference;

FIG. 9 is a characteristic graph illustrating the relationship between the height of convex parts of a dielectric layer and the frequency temperature characteristic difference;

FIG. 10 is a characteristic graph illustrating the relationship between the height of a dielectric layer and the height of convex-concave parts to make the frequency temperature characteristic difference zero;

FIGS. 11A and 11B are model views illustrating a displacement distribution of waves in the case where convex-concave parts are not formed in a surface of a dielectric layer;

FIGS. 12A and 12B are model views illustrating a displacement distribution of waves in the case where convex-concave parts are formed in a surface of a dielectric layer;

FIGS. 13A to 13F are sectional views illustrating parts of a first process for producing the elastic wave device according to the embodiment;

FIGS. 14A to 14D are sectional views illustrating parts of a second process for producing the elastic wave device according to the embodiment;

FIG. 15 is a plan view illustrating a filter device having the elastic wave device according to the embodiment;

FIG. 16 is a block diagram illustrating a communication module having the filter device according to the embodiment; and

FIG. 17 is a block diagram illustrating a communication apparatus having the communication module according to the embodiment.

### DESCRIPTION OF EMBODIMENTS

When a resonator having comb-like electrodes is produced from the elastic wave device disclosed in JP-A-2003-209458 or Japanese Patent No. 3841053, the resonance frequency and antiresonance frequency of the resonator have different temperature characteristics. Particularly when an LiNbO₃ substrate having a large electromechanical coupling factor is used, the difference between temperature characteristics of the resonance frequency and antiresonance frequency may reach 20-30 ppm/° C. For this reason, the temperature characteristic of the antiresonance frequency becomes a large value of +30 ppm/° C. even when the temperature characteristic of the resonance frequency can be set at 0 ppm/° C. Or when filter devices using such elastic wave devices are connected like a ladder to thereby form a ladder filter, the difference between temperature characteristics of the high frequency side and the low frequency side with respect to the pass band of the filter becomes so large that both temperature characteristics of the high frequency side and low frequency side cannot be kept within a given numerical value range (e.g., ±5 ppm/° C.). As a result, when the temperature of the elastic wave device changes, standard specifications cannot be met, bandwidths may change, or other negative effects may arise.

It is therefore necessary to reduce the difference between temperature characteristics of the resonance frequency and antiresonance frequency.

An elastic wave device according to an embodiment includes a piezoelectric substrate, comb-like electrodes formed on the piezoelectric substrate, and a dielectric layer formed on the piezoelectric substrate so that the comb-like electrodes are covered with the dielectric layer. The thickness of the dielectric layer formed on the piezoelectric substrate is larger than the sum of the thickness of the comb-like electrodes and the thickness of the dielectric layer formed on the comb-like electrodes.

According to this embodiment, the difference between elastic wave energy distributions of the resonance frequency and antiresonance frequency may be reduced. Accordingly, the difference between temperature characteristics of the resonance frequency and antiresonance frequency may be reduced, so that the elastic wave device may operate in a stable manner even when the temperature of the device changes.

This embodiment provides an elastic wave device which includes a piezoelectric substrate, comb-like electrodes formed on the piezoelectric substrate, and a dielectric layer formed on the piezoelectric substrate so that the comb-like electrodes are covered with the dielectric layer, wherein the thickness of the dielectric layer formed on the piezoelectric substrate is larger than the sum of the thickness of the comb-like electrodes and the thickness of the dielectric layer formed on the comb-like electrodes. According to this structure, the difference between elastic wave energy distributions of the resonance frequency and antiresonance frequency can be reduced so that the difference between temperature characteristics of the resonance frequency and antiresonance frequency can be reduced.

The elastic wave device according to this embodiment may take the following mode in addition to the aforementioned structure as a base. That is, in the elastic wave device according to this embodiment, the piezoelectric substrate may be made of lithium niobate or lithium tantalate.

The dielectric layer may contain silicon oxide as a main component.

The comb-like electrodes may be made of a material having a higher density than that of the dielectric layer.

The comb-like electrodes may contain copper or an alloy containing copper as a main component.

A filter device according to an embodiment includes an input electrode, at least one resonator which passes only an electric signal with a given frequency among electric signals input through the input electrode, and an output electrode which outputs the electric signal having passed through the resonator to the outside. The resonator has an elastic wave device which has a piezoelectric substrate, comb-like electrodes formed on the piezoelectric substrate, and a dielectric layer formed on the piezoelectric substrate so that the comb-like electrodes are covered with the dielectric layer. The elastic wave device is formed so that the thickness of the dielectric layer formed on the piezoelectric substrate is larger than the sum of the thickness of the comb-like electrodes and the thickness of the dielectric layer formed on the comb-like electrodes. According to this structure, the difference between elastic wave energy distributions of the resonance frequency and antiresonance frequency can be reduced, so that a filter device having an elastic wave device with a small difference between temperature characteristics of the resonance frequency and antiresonance frequency can be achieved. In addition, the difference between temperature characteristics of the high frequency side and low frequency side of the pass band of the filter device can be reduced.

A communication module according to an embodiment includes the aforementioned filter device.

A communication apparatus according to an embodiment includes the aforementioned communication module.

### Embodiments

### 1. Elastic Wave Device

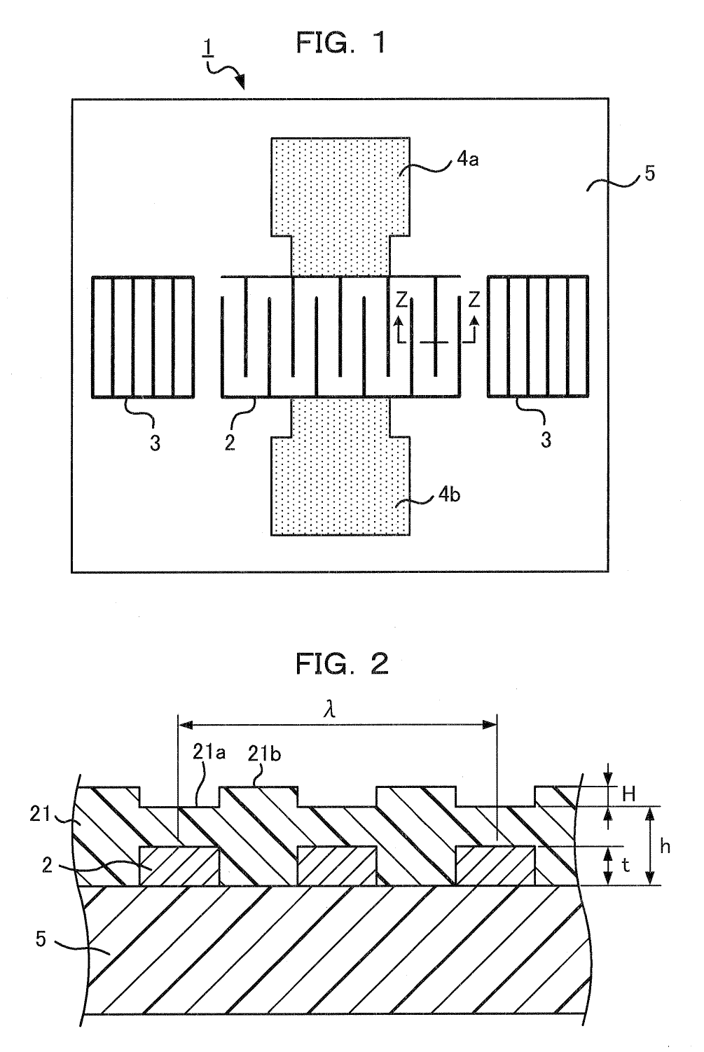

FIG. 1 is a plan view of an elastic wave device according to Embodiment 1. In FIG. 1, the elastic wave device 1 includes a piezoelectric substrate 5, comb-like electrodes 2 formed on the piezoelectric substrate 5, reflection portions 3 formed on the piezoelectric substrate 5 so as to be disposed on opposite sides of the comb-like electrodes 2, and terminal electrodes 4a and 4b formed on the piezoelectric substrate 5 so as to be disposed on opposite sides of the comb-like electrodes 2. When, for example, an electric signal is applied to the terminal electrode 4a, the piezoelectric substrate 5 vibrates to generate surface acoustic waves with a given wavelength based on the cycle of the comb-like electrodes 2. An electric signal with a given frequency can be taken from the terminal electrode 4b based on the generated surface acoustic waves. The piezoelectric substrate 5 is preferably made of lithium niobate (LiNbO₃) or lithium tantalate (LiTaO₃), the comb-like electrodes 2 are preferably made of a material having a higher density than that of a dielectric film (SiO₂ film), and the comb-like electrodes 2 are preferably made of copper (Cu) or an alloy containing Cu as a main component so that the elastic wave device 1 can generate Love waves. The elastic wave device according to this embodiment can be applied not only to a device for generating Love waves but also to a device for generating other elastic waves.

FIG. 2 is a sectional view along the line Z-Z in FIG. 1. As illustrated in FIG. 2, in the elastic wave device 1 according to this embodiment, the comb-like electrodes 2 containing Cu as a main component are formed on the piezoelectric substrate 5 provided as a rotated Y-cut plate (e.g., 0° Y), and an SiO₂ film (dielectric film) 21 is formed on the comb-like electrodes 2 and the piezoelectric substrate 5. In this embodiment, the SiO₂ film 21 is formed so that the surface of the SiO₂ film 21 is not flat. The SiO₂ film 21 is formed so that the film protrudes more between the comb-like electrode 2 fingers than on top of the comb-like electrode fingers. Accordingly, the SiO₂ film 21 is formed so that the thickness of the SiO₂ film 21 on the piezoelectric substrate 5 is larger than the sum of the thickness of the comb-like electrodes 2 and the thickness of the SiO₂ film 21 formed on the comb-like electrodes 2. Parts of the SiO₂ film 21 formed on the comb-like electrodes 2 are referred to as concave parts 21a whereas parts of the SiO₂ film 21 between the fingers of the comb-like electrodes 2 are referred to as convex parts 21b. The wavelength of elastic waves in the elastic wave device 1 is defined as λ, the thickness of the fingers of the comb-like electrodes 2 is defined as t, the thickness of the SiO₂ film 21 (concave parts 21a) is defined as h, and the height of the protruding parts of the convex parts 21b of the SiO₂ film 21 between fingers of the comb-like electrodes 2 is defined as H. The height H is a quantity of protrusion of the convex parts 21b relative to the concave parts 21a. The direction of propagation of waves is in the X-axis direction of the piezoelectric substrate 5.

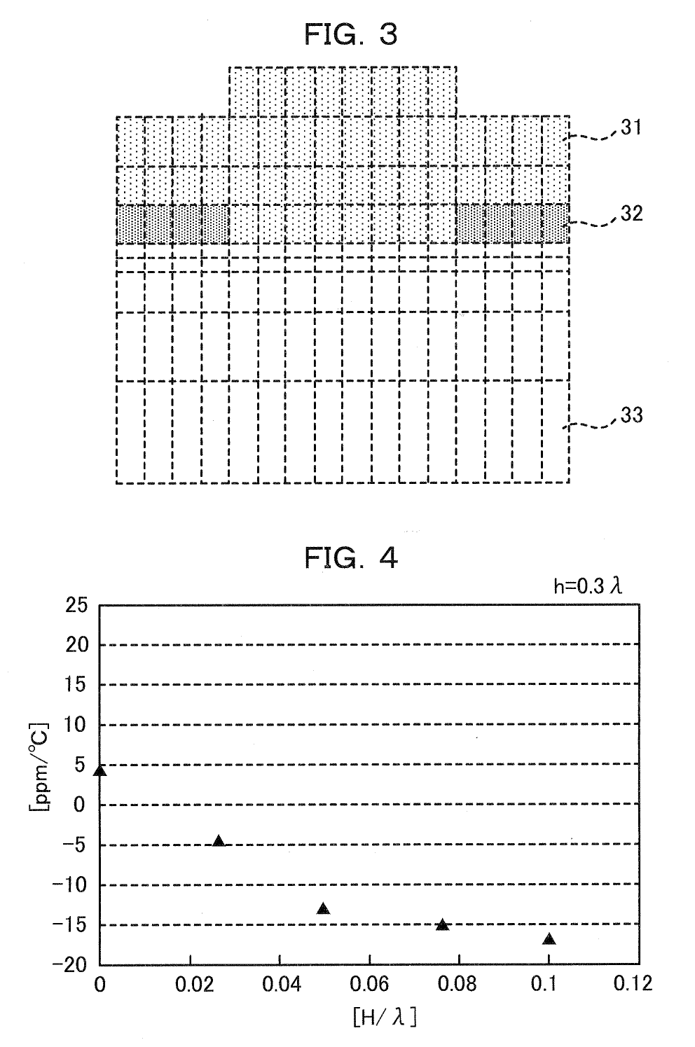

The inventors made a simulation based on a finite element method (FEM) to calculate frequency temperature characteristics in resonance frequencies and antiresonance frequencies under various structures. FIG. 3 illustrates an FEM simulation model. The model illustrated in FIG. 3 is a model for calculating infinite repetition of a basic unit under the condition that one finger of the comb-like electrodes 2 illustrated in FIG. 2 is regarded as the basic unit. In FIG. 3, a region 31 expresses a model of the SiO₂ film 21, a region 32 expresses a model of the comb-like electrodes 2, and a region 33 expresses a model of the piezoelectric substrate 5. Calculation was performed where the comb-like electrodes 2 were made of Cu (density=8.92 kg/m³) and the film thickness of the comb-like electrodes 2 was set at 100 nm.

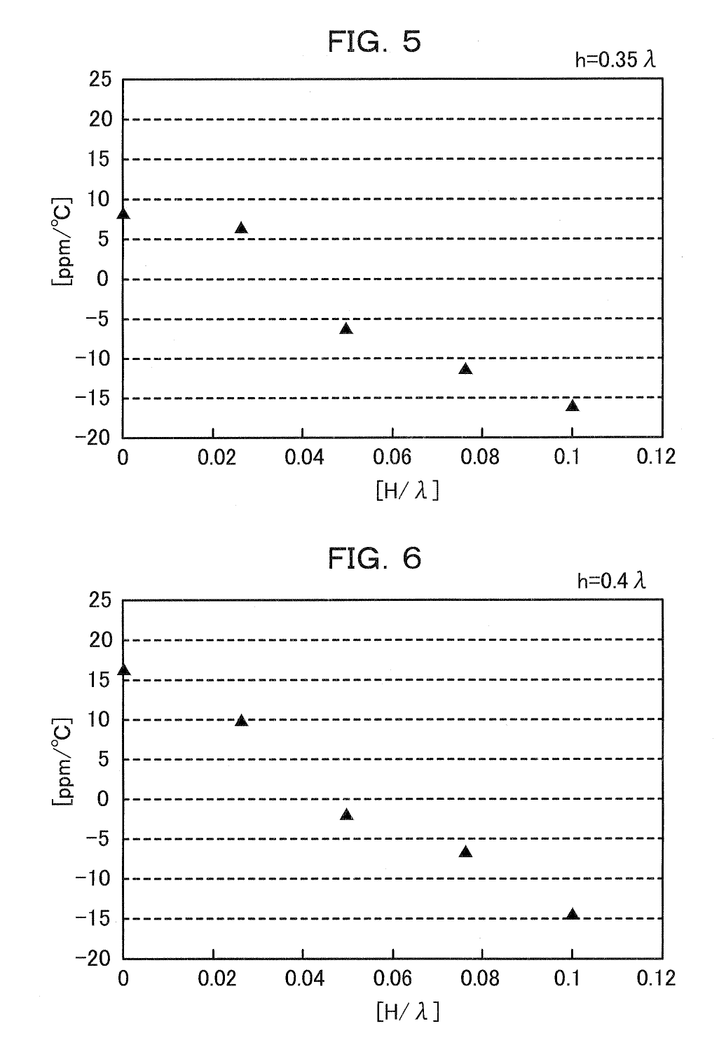

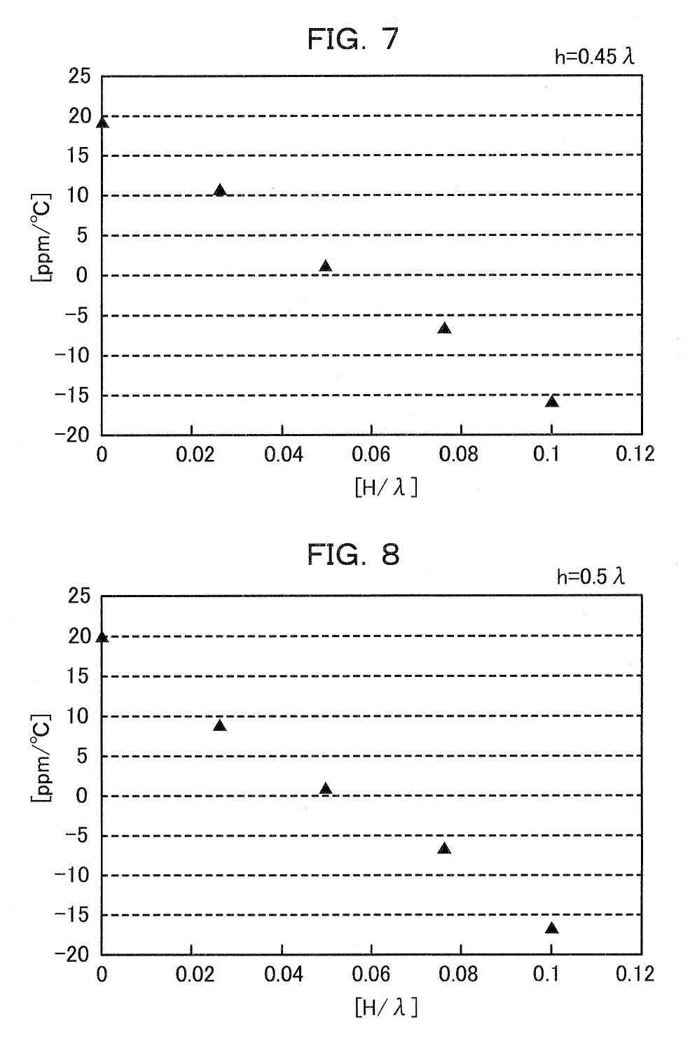

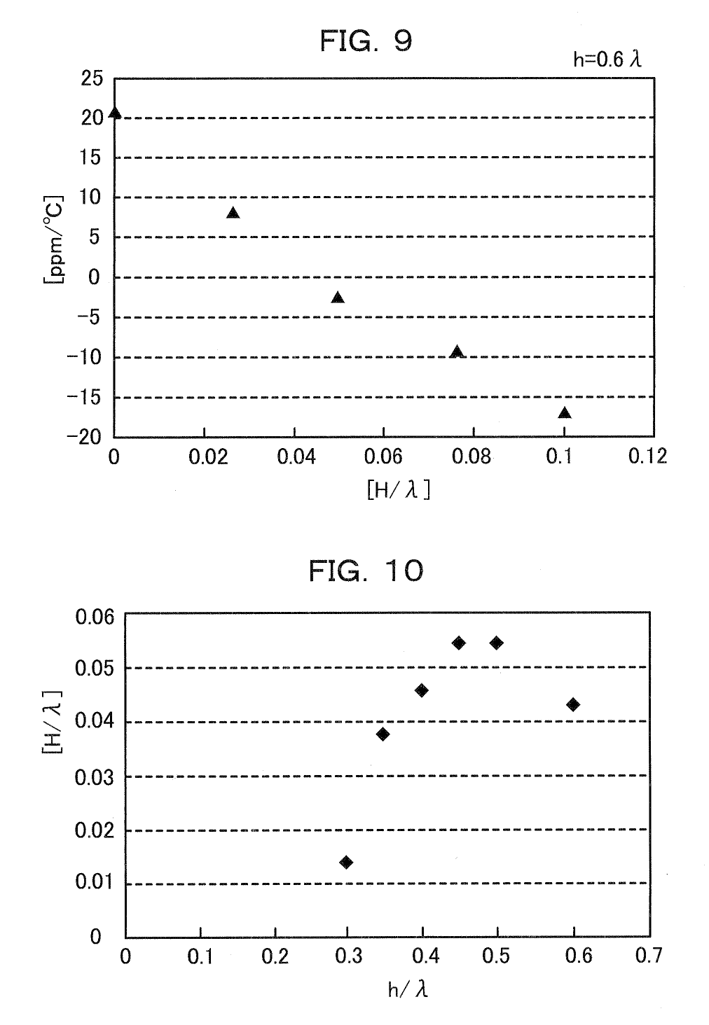

FIGS. 4 to 9 illustrate results of finite element method-based measurement of the model illustrated in FIG. 3. Samples were produced with the height ratio (H/λ) of the convex parts 21b of the SiO₂ film 21 changed to 0, 0.025, 0.05, 0.075, and 0.1. The frequency temperature characteristic difference between the resonance frequency and the antiresonance frequency of each SiO₂ film 21 was measured. The height ratio H/λ=0 is equivalent to the conventional structure having no convex parts 21b. FIG. 4 illustrates a result of calculation at h=0.3λ. FIG. 5 illustrates a result of calculation at h=0.35λ. FIG. 6 illustrates a result of calculation at h=0.4λ. FIG. 7 illustrates a result of calculation at h=0.45λ. FIG. 8 illustrates a result of calculation at h=0.5X. FIG. 9 illustrates a result of calculation at h=0.6λ.

Although this calculation was performed on the case where the cycle λ of fingers of the comb-like electrodes 2 was set at 2 μm, there is no reason that the result of the calculation can apply only to the case where the cycle λ is 2 μm. Therefore, the height H of SiO₂ between fingers of the comb-like electrodes 2 in each of FIGS. 4 to 9 is illustrated as a value standardized by λ. Each of the temperature characteristics of the resonance frequency and antiresonance frequency is expressed as a temperature coefficient of frequency, which is the rate of change of frequency when the temperature changes by +1° C. That is, each of the temperature characteristics of the resonance frequency and antiresonance frequency is expressed in ppm/° C. Incidentally, the temperature coefficient is not limited to the temperature coefficient of frequency (TCF) and may be a temperature coefficient of velocity (TCV) or a temperature coefficient of delay time (TCD). Accordingly, the values plotted in each of the graphs of FIGS. 4 to 9 satisfy the following expression.

Temperature Characteristic Difference=Temperature Characteristic of Resonance Frequency−Temperature Characteristic of Antiresonance Frequency

As illustrated in FIG. 4, the temperature characteristic difference is a plus value regardless of the thickness h of the SiO₂ film 21 when the height of the convex parts 21b of the SiO₂ film 21 is H=0 (that is, when the SiO₂ film 21 is flat without any convex and concave parts), and the temperature characteristic difference decreases monotonously as the height ratio H/λ of the protrusions increases. In the middle of the monotonous decrease of the temperature characteristic difference, the temperature characteristic difference approaches zero when the height ratio H/λ of the protrusions is in a range from 0.01 to 0.06. Thus it can be said that the difference between temperature characteristics of the resonance frequency and antiresonance frequency may be brought near to zero when the height of the SiO₂ film 21 (convex parts 21b) between fingers of the comb-like electrodes 2 is set to be larger by a value of 0.01λ to 0.06λ than the height of the SiO₂ film 21 (concave parts 21a) on the comb-like electrodes 2.

FIG. 10 is a graph illustrating the case where values of the height ratio H/λ of the protrusions provided so that the difference between temperature characteristics of the resonance frequency and antiresonance frequency at the height h of each SiO₂ film 21 approaching zero are plotted as obtained from results of the calculation illustrated in FIGS. 4 to 9. As illustrated in FIG. 10, in the structure on which calculation was performed in this embodiment, it is found that the difference between temperature characteristics of the resonance frequency and antiresonance frequency is brought near to zero when the height ratio H/λ of the protrusions is in a range from 0.01 to 0.06.

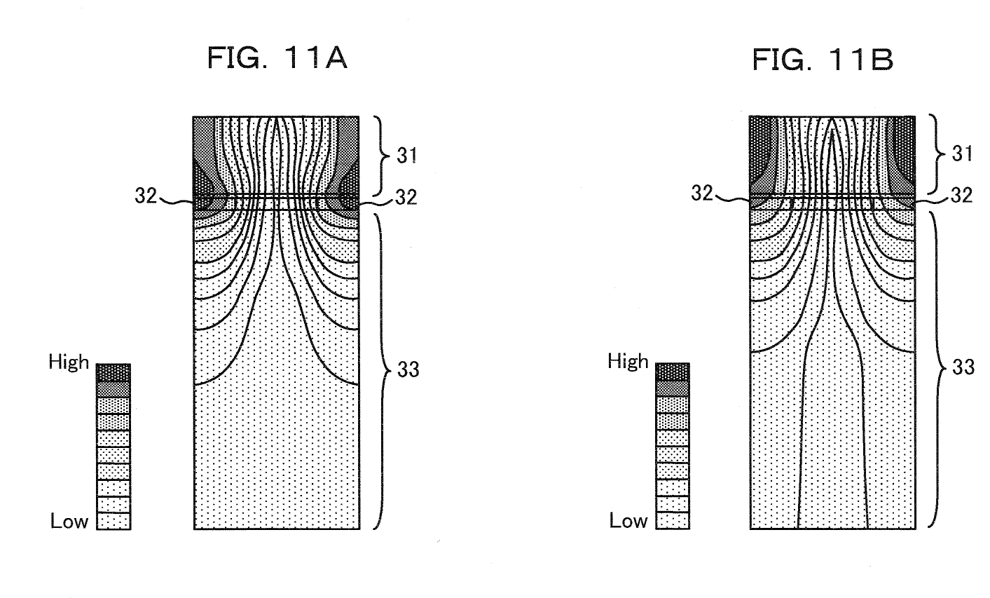

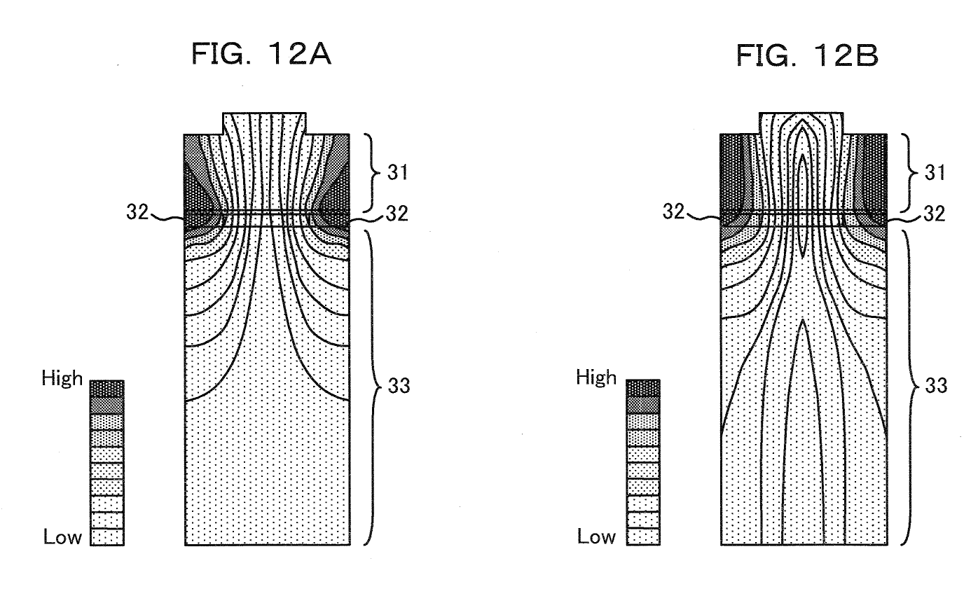

FIGS. 11A, 11B, 12A, and 12B are views illustrating displacement distributions of waves in the FEM simulation model illustrated in FIG. 2 and for consideration of the physical meaning of this embodiment. The displacement distribution illustrated in each of FIGS. 11A, 11B, 12A, and 12B is substantially equal to an energy distribution of waves. In each of FIGS. 11A, 11B, 12A, and 12B, a high dot density portion expresses a large displacement (e.g., high wave energy), and a low dot density portion expresses a small displacement (e.g., low wave energy). FIG. 11A illustrates the displacement distribution of waves at a resonance frequency in an elastic wave device having the conventional structure in which convex and concave parts are not formed in the SiO₂ film. FIG. 11B illustrates the displacement distribution of waves at an antiresonance frequency in the elastic wave device. FIG. 12A illustrates the displacement distribution of waves at a resonance frequency in an elastic wave device having the structure (in which convex and concave parts are formed in the SiO₂ film) according to this embodiment. FIG. 12B illustrates the displacement distribution of waves at an antiresonance frequency in the elastic wave device.

It is found that energy is concentrated into the surface of the SiO₂ film (that is, into the upper side of the region 31 in each of FIGS. 11A, 11B, 12A, and 12B) because the elastic wave device is provided to propagate surface acoustic waves. As illustrated in FIGS. 11A and 12A, the difference between displacement (energy) distributions of waves at the resonance frequency based on the presence or absence of convex and concave parts in the SiO₂ film is small. AS illustrated in FIGS. 11B and 12B, at the antiresonance frequency, the presence of convex and concave parts (FIG. 12B) permits the large wave displacement (energy) region to be spread near the comb-like electrodes (region 32). For this reason, it is considered that the difference between temperature characteristics is reduced because the difference between displacement (energy) distributions of waves at the resonance frequency and the antiresonance frequency is reduced by the presence of convex and concave parts in the SiO₂ film as illustrated in FIGS. 12A and 12B. That is, in the conventional displacement distributions illustrated in FIGS. 11A and 11B, the large wave displacement portion is concentrated in the neighborhood of the comb-like electrodes (region 32) in the case of the resonance frequency as illustrated in FIG. 11A, while the large wave displacement portion is concentrated in the neighborhood of the surface of the SiO₂ film (region 31) in the case of the antiresonance frequency as illustrated in FIG. 11B. On the other hand, in the displacement distributions according to this embodiment illustrated in FIGS. 12A and 12B, the large wave displacement portion is concentrated in the neighborhood of the comb-like electrodes (region 32) in both cases of the resonance frequency and the antiresonance frequency. Accordingly, it is found that the difference between temperature characteristics in this embodiment is reduced because the difference between displacement (energy) distributions of waves at the resonance frequency and the antiresonance frequency is reduced.

### 2. Method of Producing Elastic Wave Device

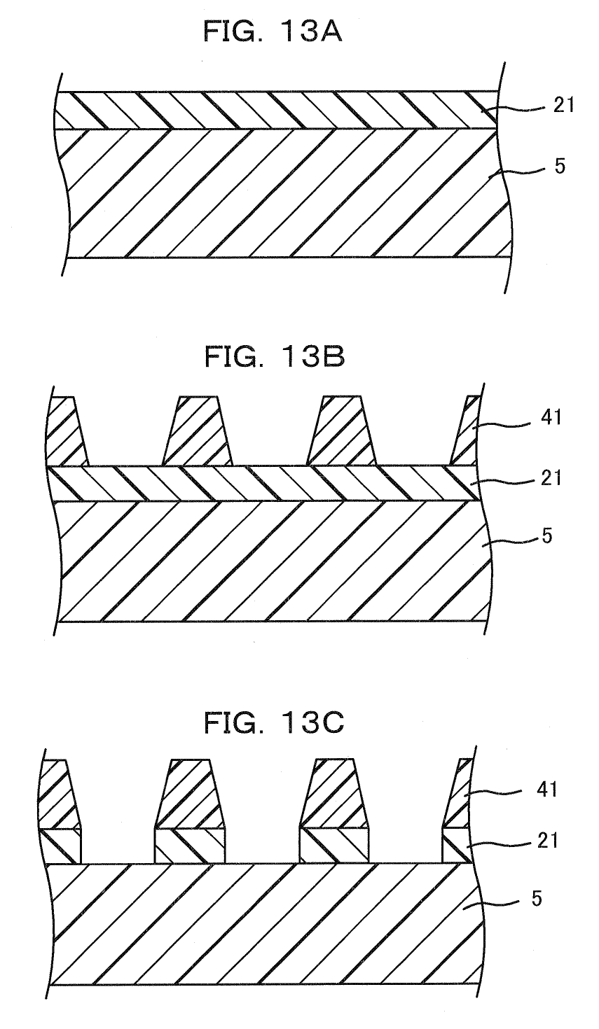

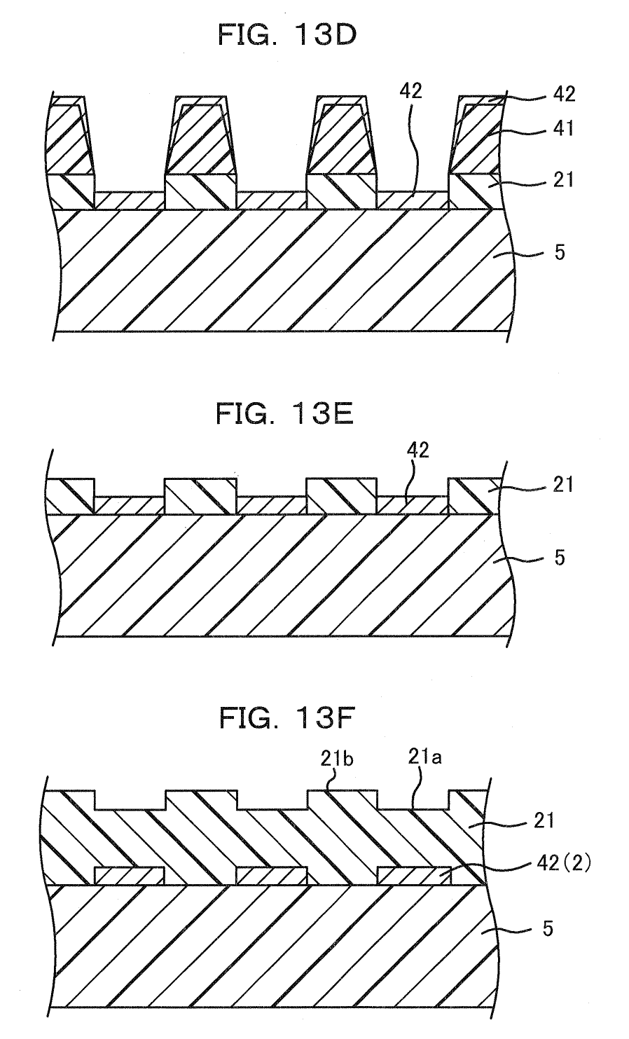

FIGS. 13A to 13F are views explaining a first method for producing an elastic wave device. Parts the same in configuration as those illustrated in FIG. 1 are referred to by the same numerals. First, as illustrated in FIG. 13A, an SiO₂ film 21 is formed on a piezoelectric substrate 5. Then, as illustrated in FIG. 13B, a resist pattern 41 is formed on regions of the SiO₂ film 21 where comb-like electrodes 2 will be not formed. Then, as illustrated in FIG. 13C, the other regions of the SiO₂ film 21 which are not covered with the resist pattern 41 are removed, for example, by dry etching. Then, as illustrated in FIG. 13D, a Cu film 42 is formed, for example, by an electron beam vapor deposition method or the like. At this point, the difference between the film thickness of the SiO₂ film 21 formed by the step illustrated in. FIG. 13A and the thickness of the Cu film 42 formed by the step illustrated in FIG. 13D is formed as the protrusion height H of the SiO₂ film 21. Then, as illustrated in FIG. 13E, the resist pattern 41 and part of the Cu film 42 deposited on the resist pattern 41 are removed by a lift-off method. Then, as illustrated in FIG. 13F, a new SiO₂ film is formed completely over the SiO₂ film 21 and the Cu film 42. As a result, an elastic wave device provided with the SiO₂ film 21 having concave parts 21a and convex parts 21b formed on its surface can be produced.

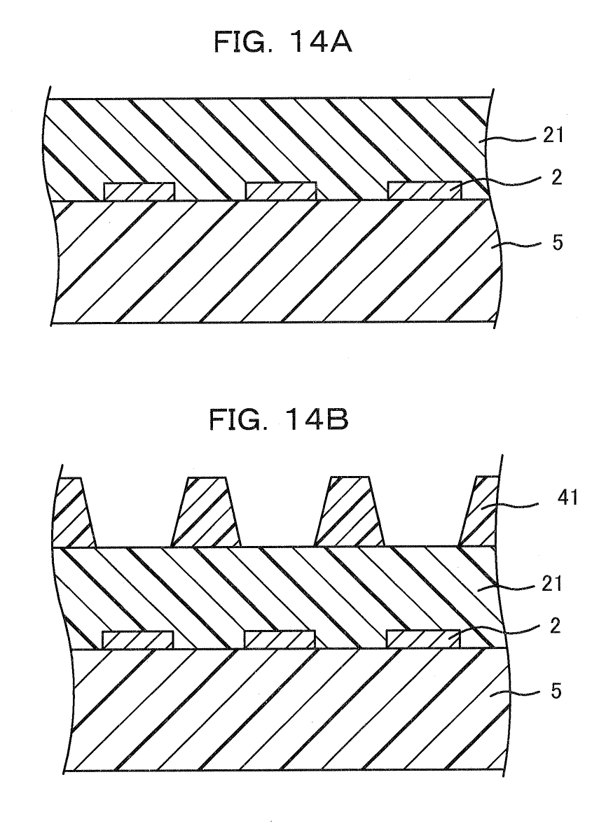

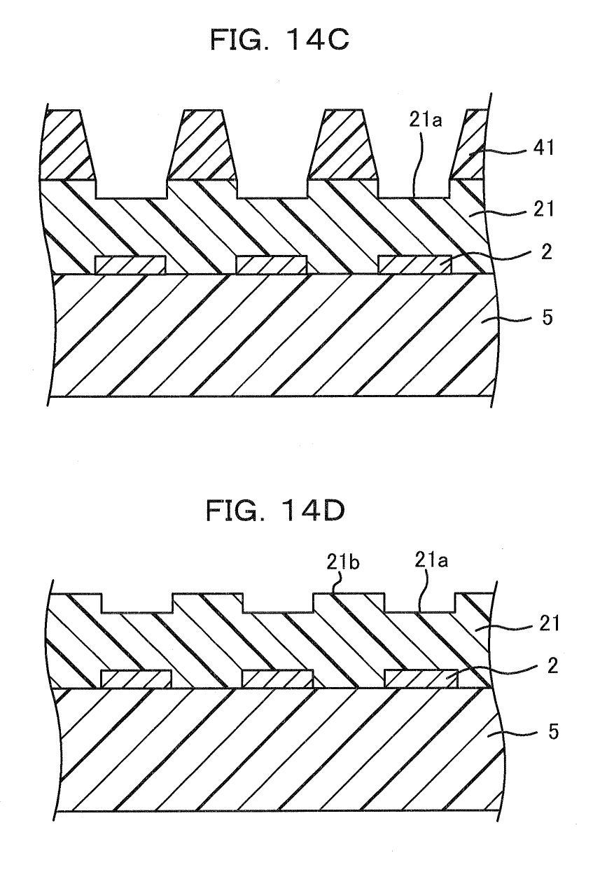

FIGS. 14A to 14D are views for explaining a second method for producing an elastic wave device. First, a device illustrated in FIG. 14A is produced, for example, by the method disclosed in Patent Document 2. The device illustrated in FIG. 14A has a piezoelectric substrate 5, comb-like electrodes 2 formed on the piezoelectric substrate 5, and an SiO₂ film 21 formed to cover the comb-like electrodes 2. The surface of the SiO₂ film 21 is flat. Then, as illustrated in FIG. 14B, a resist pattern 41 is formed on the surface of the SiO₂ film 21. Then, as illustrated in FIG. 14C, the SiO₂ film 21 on the comb-like electrodes 2 is removed by a corrosion method such as dry etching to thereby form concave parts 21a. In this step, the SiO₂ film 21 is removed down to a depth corresponding to the height H of the protrusions. Then, as illustrated in FIG. 14D, the resist pattern 41 is removed.

In the state illustrated in FIG. 14A, concave and convex parts have been not formed on the surface of the SiO₂ film 21 yet. Even when the SiO₂ film 21 on the comb-like electrodes 2 is thicker than the SiO₂ film 21 between teeth of the comb-like electrodes 2, an elastic wave device in which the SiO₂ film 21 between teeth of the comb-like electrodes 2 is thick can be produced by controlling the quantity of etching in the step illustrated in FIG. 14C.

The second producing method can provide easy and low-cost production because the number of steps in the second producing method is smaller than that in the first producing method.

### 3. Band-Pass Filter

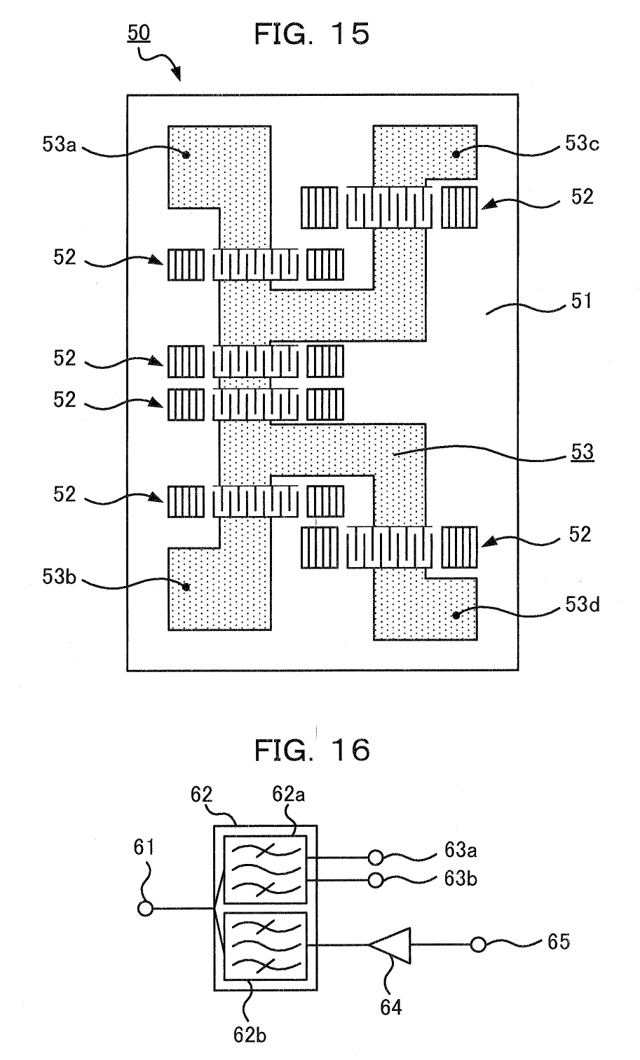

FIG. 15 illustrates an example of a band-pass filter equipped with elastic wave devices according to this embodiment. The band-pass filter 50 illustrated in FIG. 15 includes a piezoelectric substrate 51, resonators 52, and a power feed wiring portion 53. The resonators 52 and the power feed wiring portion 53 are formed on the piezoelectric substrate 51. Each of the resonators 52 has an elastic wave device according to this embodiment. The power feed wiring portion 53 has an input terminal 53a, an output terminal 53b, and ground terminals 53c and 53d. An electric signal input to the input terminal 53a is filtered based on the resonance frequency and antiresonance frequency set by each resonator 52, so that an electric signal with a given frequency is output from the output terminal 53b. The band-pass filter 50 is an example of a filter device.

The provision of the resonators 52 each having an elastic wave device according to this embodiment permits achievement of a band-pass filter in which the difference between temperature characteristics of the resonance frequency and antiresonance frequency is so small that stability against the change of temperature can be obtained.

### 4. Communication Module

FIG. 16 illustrates an example of a communication module equipped with elastic wave devices according to this embodiment. As illustrated in FIG. 16, a duplexer 62 includes a reception filter 62a and a transmission filter 62b. For example, reception terminals 63a and 63b corresponding to balance output are connected to the reception filter 62a. The transmission filter 62b is connected to a transmission terminal 65 through a power amplifier 64. The reception filter 62a and the transmission filter 62b include elastic wave devices according to this embodiment or band-pass filters equipped with elastic wave devices according to this embodiment.

For a receiving operation, the reception filter 62a allows only a signal of a given frequency band among reception signals input through an antenna terminal 61 to pass and outputs the signal from the reception terminals 63a and 63b to the outside. For a transmitting operation, the transmission filter 62b allows only a signal of a given frequency band among transmission signals input from the transmission terminal 65 and amplified by the power amplifier 64 to pass and outputs the signal from the antenna terminal 61 to the outside.

The provision of the reception filter 62a and the transmission filter 62b (communication module) equipped with elastic wave devices according to this embodiment as described above permits achievement of a communication module in which the difference between temperature characteristics of the resonance frequency and antiresonance frequency is so small that stability against the change of temperature can be obtained.

The communication module illustrated in FIG. 16 is an example and the same effect can be obtained when the elastic wave devices or band-pass filters according to this embodiment are mounted in another type communication module.

### 5. Communication Apparatus

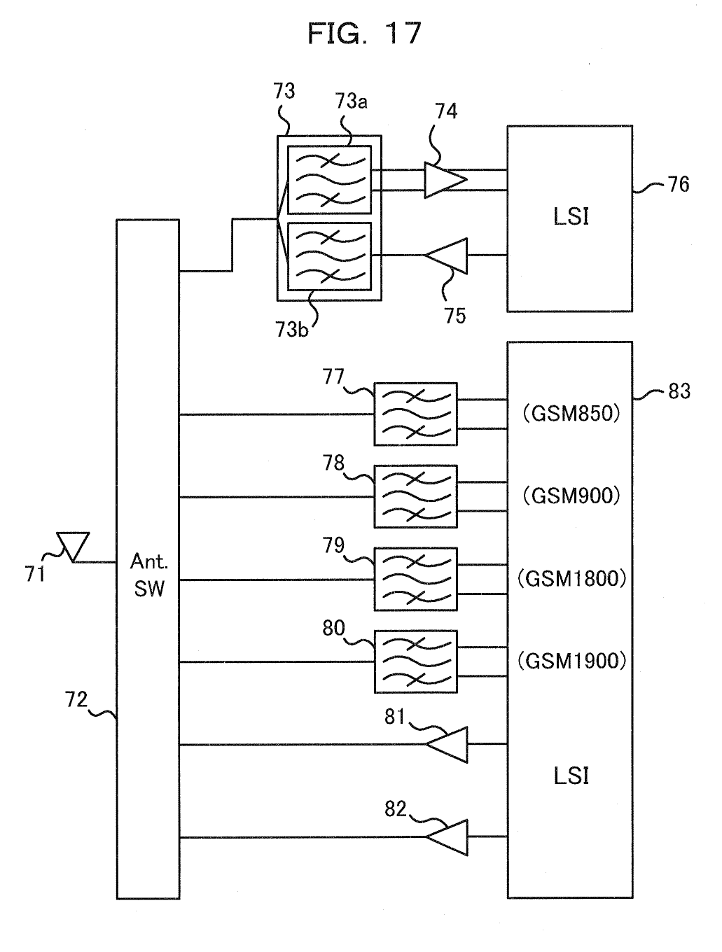

FIG. 17 illustrates an RF block of a cellular phone terminal as an example of a communication apparatus equipped with elastic wave devices according to this embodiment. FIG. 17 illustrates a cellular phone terminal compliant with a Global System for Mobile Communications (GSM) communication method and a Wideband Code Division Multiple Access (W-CDMA) communication method. The GSM communication method in this embodiment supports an 850 MHz band, a 950 MHz band, a 1.8 GHz band, and a 1.9 GHz band. Although the cellular phone terminal includes a microphone, a speaker, a liquid crystal display, in addition to the configuration illustrated in FIG. 17, description of the parts unnecessary for description of this embodiment will be omitted. Reception filters 73a, 77, 78, 79, and 80 and a transmission filter 73b include elastic wave devices according to this embodiment.

First, if a reception signal is input through an antenna 71, an antenna switch circuit 72 selects an LSI as a target of operation in accordance with whether the communication method of the reception signal is W-CDMA or GSM. When the input reception signal supports the W-CDMA communication method, the antenna switch circuit 72 performs switching so that the reception signal is output to a duplexer 73. The reception signal input to the duplexer 73 is limited to a given frequency band by a reception filter 73a, so that a balance type reception signal is output to an Low Noise Amp (LNA) 74. The LNA 74 amplifies the input reception signal and outputs the amplified signal to an LSI 76. The LSI 76 performs decoding to an audio signal based on the input reception signal or controlling operations of respective portions in the cellular phone terminal.

On the other hand, for signal transmission, the LSI 76 generates a transmission signal. The generated transmission signal is amplified by a power amplifier 75 and input to a transmission filter 73b. The transmission filter 73b allows only a signal of a given frequency band among the input transmission signals to pass. The transmission signal output from the transmission filter 73b is output from the antenna 71 to the outside through the antenna switch circuit 72.

If the input reception signal supports the GSM communication method, the antenna switch circuit 72 selects any one of the reception filters 77 to 80 in accordance with the frequency band so as to output the reception signal to the selected reception filter. The reception signal the band of which is limited by any one of the reception filters 77 to 80 is input to an LSI 83. The LSI 83 performs demodulation to an audio signal based on the input reception signal or controlling operations of respective portions in the cellular phone terminal. On the other hand, for signal transmission, the LSI 83 generates a transmission signal. The generated transmission signal is amplified by a power amplifier 81 or 82 and output from the antenna 71 to the outside through the antenna switch circuit 72.

The provision of the communication apparatus equipped with elastic wave devices according to this embodiment as described above permits achievement of a communication apparatus in which the difference between temperature characteristics of the resonance frequency and antiresonance frequency is so small that stability against the change of temperature can be obtained.

### 6. Effects of the Embodiment

According to this embodiment, since convex parts 21b of a given height are formed on the surface of the SiO₂ film 21, it is possible to reduce the difference between temperature characteristics of the resonance frequency and antiresonance frequency or the difference between temperature characteristics of the high-frequency side and low-frequency side of the bass band of a filter.

The achievement of reduction of the difference between temperature characteristics permits achievement of an elastic wave device with desirable temperature characteristics so that, for example, both temperature characteristics of the high-frequency side and low-frequency side of the pass band are within ±5 ppm/° C.

Moreover, large changes of the filter characteristics may be suppressed even when the temperature of the elastic wave device changes.

The elastic wave device according to this embodiment is useful for an apparatus capable of receiving or transmitting a signal with a given frequency.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

1. An elastic wave device comprising a piezoelectric substrate, comb-like electrodes formed on the piezoelectric substrate, and a dielectric layer formed on the piezoelectric substrate so that the comb-like electrodes are covered with the dielectric layer, wherein the thickness of the dielectric layer formed on the piezoelectric substrate is larger than the sum of the thickness of the comb-like electrodes and the thickness of the dielectric layer formed on the comb-like electrodes.

2. An elastic wave device according to claim 1, wherein the piezoelectric substrate is made of lithium niobate or lithium tantalate.

3. An elastic wave device according to claim 1, wherein the dielectric layer contains silicon oxide as a main component.

4. An elastic wave device according to claim 1, wherein the comb-like electrodes are made of a material having a larger density than that of the dielectric layer.

5. An elastic wave device according to claim 1, wherein the comb-like electrodes contain copper or an alloy containing copper as a main component.

6. A filter device comprising an input electrode, at least one resonator which allows only an electric signal of a given frequency among electric signals input through the input electrode to pass, and an output electrode which outputs the electric signal having passed through the resonator to the outside, wherein:
the resonator includes an elastic wave device which has a piezoelectric substrate, comb-like electrodes formed on the piezoelectric substrate, and a dielectric layer formed on the piezoelectric substrate so that the comb-like electrodes are covered with the dielectric layer; and
the elastic wave device is formed so that the thickness of the dielectric layer formed on the piezoelectric substrate is larger than the sum of the thickness of the comb-like electrodes and the thickness of the dielectric layer formed on the comb-like electrodes.

7. A communication module comprising a filter device according to claim 6.

8. A communication apparatus comprising a communication module according to claim 7.
